(19) United States
(12) Patent Application Publication
(10) Pub. No.: US 2025/0271484 A1
(43) Pub. Date: Aug. 28, 2025

(54) Line Impedance Stabilization Network

(71) Applicant: Mississippi State University, MIssissippi State, MS (US)

(72) Inventors: Seungdeog Choi, Starkville, MS (US); Tahmid Ibne Mannan, Starkville, MS (US)

(21) Appl. No.: 19/061,303

(22) Filed: Feb. 24, 2025

Related U.S. Application Data
(60) Provisional application No. 63/557,120, filed on Feb. 23, 2024.

(51) Int. Cl. G01R 31/00

(52) U.S. Cl. CPC G01R 31/001

(57) ABSTRACT

A line impedance stabilization network (LISN) is disclosed. The LISN includes an inductor that defines a first circuit node and a second circuit node and that has a first parasitic resistance, a second parasitic resistance, and a first parasitic capacitance. The LISN further includes a first capacitor that is connected to the first circuit node, that defines a third circuit node, and that has a first parasitic inductance, and a third parasitic resistance. The LISN further includes a second capacitor that is connected to the second circuit node, that defines a fourth circuit node, and that has a second parasitic inductance and a fourth parasitic resistance. The LISN further includes a resistor that is connected to the fourth circuit node and the third circuit node. A configuration of the first circuit node generates a first mutual inductance. A configuration of the second circuit node generates a second mutual inductance.

### CROSS-REFERENCE TO RELATED APPLICATION

This application claims the benefit of U.S. Application 63/557, 120, filed Feb. 23, 2024, which is incorporated by reference.

### STATEMENT REGARDING FEDERALLY SPONSORED RESEARCH OR DEVELOPMENT

This invention was made with government support under Grant Number N00014-21-1-2124 and Grant DCN Number 543-2070-24, both awarded by the US Office of Naval Research. The government has certain rights in the invention.

### BACKGROUND

A line impedance stabilization network (LISN) is a device used in conducted and radiated radio-frequency emission and susceptibility tests, as specified in various electromagnetic compatibility test standards. A LISN is a low-pass filter typically placed between an alternating current (AC) or direct current (DC) power source and the equipment under test (EUT) to create a known impedance and to provide a radio frequency (RF) noise measurement port. It also isolates the unwanted RF signals from the power source.

### SUMMARY

An innovative aspect of the subject matter described in this specification may be implemented in a line impedance stabilization network (LISN) that includes an inductor that defines a first circuit node and a second circuit node and that has a first parasitic resistance, a second parasitic resistance, and a first parasitic capacitance. The LISN includes a first capacitor that is connected to the first circuit node, that defines a third circuit node, and that has a first parasitic inductance, and a third parasitic resistance. The LISN includes a second capacitor that is connected to the second circuit node, that defines a fourth circuit node, and that has a second parasitic inductance and a fourth parasitic resistance. The LISN includes a resistor that is connected to the fourth circuit node and the third circuit node. A configuration of the first circuit node generates a first mutual inductance that is based on the first parasitic resistance, the second parasitic resistance, the first parasitic capacitance, the first parasitic inductance, the third parasitic resistance, the second parasitic inductance, and the fourth parasitic resistance. A configuration of the second circuit node generates a second mutual inductance that is based on the first parasitic resistance, the second parasitic resistance, the first parasitic capacitance, the first parasitic inductance, the third parasitic resistance, the second parasitic inductance, and the fourth parasitic resistance.

Another innovative aspect of the subject matter described in this specification may be implemented in a method that includes the actions of determining, for an inductor of a line impedance stabilization network, a first parasitic resistance, a second parasitic resistance, and a first parasitic capacitance. The actions include determining, for a first capacitor of the line impedance stabilization network, a first parasitic inductance and a third parasitic resistance. The actions include determining, for a second capacitor of the line impedance stabilization network, a second parasitic inductance and a fourth parasitic resistance. Based on the first parasitic resistance, the second parasitic resistance, the first parasitic capacitance, the first parasitic inductance, the third parasitic resistance, the second parasitic inductance, and the fourth parasitic resistance, the actions include determining a configuration of a power supply port of the line impedance stabilization network. Based on the first parasitic resistance, the second parasitic resistance, the first parasitic capacitance, the first parasitic inductance, the third parasitic resistance, the second parasitic inductance, and the fourth parasitic resistance, the actions include determining a configuration of a device under test port of the line impedance stabilization network.

Other implementations of this aspect include corresponding systems, apparatus, and computer programs recorded on computer storage devices, each configured to perform the operations of the method.

Another innovative aspect of the subject matter described in this specification may be implemented in a line impedance stabilization network that includes a first inductor that defines a first circuit node and a second circuit node. The LISN includes a first capacitor that defines a third circuit node and a fourth circuit node. The LISN includes a second capacitor that defines a fifth circuit node and a sixth circuit node. The LISN includes a resistor that is connected to the sixth circuit node and fourth circuit node. The LISN includes a second inductor that defines a seventh circuit node and is connected to the third circuit node. The LISN includes a third inductor that is connected to the first circuit node and the third circuit node. The LISN includes a fourth inductor that is connected to second circuit node and the fifth circuit node. The LISN includes a fifth inductor that is connected to the fifth circuit node and that defines the eighth circuit node.

### BRIEF DESCRIPTION OF THE DRAWINGS

For a more complete understanding of the present disclosure, reference is now made to the following brief description, taken in connection with the accompanying drawings and detailed description, wherein like reference numerals represent like parts.

FIG. 1 illustrates an example electromagnetic interference (EMI) measurement setup with LISN.

FIG. 2 illustrates an example International Special Committee on Radio Interference (CISPR) 16-1-2 compliant 50 μH/50Ω LISN circuit.

FIG. 3 illustrates an example equivalent LISN circuit with parasitic parameters and its terminals.

FIG. 4 illustrates an example experimentally measured impedance magnitude comparison between ideal and example components, where part (a) illustrates a 0.22 μF capacitor and part (b) illustrates a 50 μH inductor.

FIG. 5 illustrates some example effects of ESL_{C2} (equivalent series inductance) and C_{P} on Z_{LISN} compared to CISPR-16 limits, where part (a) illustrates magnitude, and part (b) illustrates phase.

FIG. 6 illustrates an example simulated bode gain plot comparison, where part (a) illustrates for voltage division factor (VDF), part (b) illustrates for DFₒᵤₜ (decoupling factor), and part (c) illustrates for DF_{DUT}.

FIG. 7 illustrates an example parametric analysis of VDF with ESL_{C2} sweep, where each curve is marked with the values of the inductance range.

FIG. 8 illustrates an example parametric analysis of Z_{LISN} magnitude, where part (a) illustrates a C_{P} sweep when ESL_{C2}<15 nH and part (b) illustrates an ESL_{C2} sweep when C_{P}<20 pF, and where each curve is marked with the values of the capacitance/inductance range.

FIG. 9 illustrates an example parametric analysis of LISN step response, where part (a) illustrates an ESL_{C2} sweep and part (b) illustrates a C_{P} sweep, and where each curve is marked with the values of the inductance/capacitance range.

FIG. 10 illustrates an example parametric analysis of DFₒᵤₜ with ESL_{C1} sweep, where each curve is marked with the values of the inductance range.

FIG. 11 illustrates an example LISN parasitic minimization and optimization process.

FIG. 12 illustrates example printed circuit board (PCB) board schematics, where part (a) illustrates the schematic for case A and part (b) illustrates the schematic for part B.

FIG. 13 illustrates various example representations of the loop traces, where part (a) illustrates coupled vertically stacked square PCB loop traces, part (b) illustrates an equivalent center-tapped coupled magnetic winding structure, and part (c) illustrates an equivalent T-model of the center-tapped structure with negative M_{TB} on the shunt path.

FIG. 14 illustrates example representations of the loop traces, where part (a) illustrates an equivalent T model of coupled loops with the device under test (DUT) side capacitor, and part (b) illustrates a reduction of ESL using M_{TB}.

FIG. 15 illustrates example simulated M_{TB} variation with loop dimension (l).

FIG. 16 illustrates an example PCB for ESL cancellation with 12 mm width square loop traces, where part (a) illustrates an ESL_{C2} cancellation top layer trace, part (b) illustrates an ESL_{C2} cancellation bottom layer trace, part (c) illustrates an ESL_{C1} cancellation top layer trace, and part (d) illustrates an ESL_{C1} cancellation bottom layer trace.

FIG. 17 illustrates example experimentally measured impedances for different cases, where part (a) illustrates ESL_{C2} cancellation and part (b) illustrates ESL_{C1} cancellation.

FIG. 18 illustrates an example parameter sweep analysis for the inductor design.

FIG. 19 illustrates example simulation results, where part (a) illustrates an L variation with frequency and part (b) illustrates C_{P} variation with p for an example inductor with parameters: N=34, D=100 mm, a=337 mm.

FIG. 20 illustrates an example medium voltage (MV) inductor with resistive damping.

FIG. 21 illustrates example experimentally measured frequency characteristics, where part (a) illustrates the characteristics for inductance and part (b) illustrates the characteristics for impedance for an example inductor.

FIG. 22 illustrates an example 1.5 kV, 75 A, 30 megahertz (MHZ) MV LISN prototype with ESL canceling PCB traces and example inductor.

FIG. 23 illustrates an example circuit schematic of a LISN with modified wiring.

FIG. 24 is a flowchart of an example process for determining wiring modifications for a LISN capable of handling medium voltage.

FIG. 25 illustrates an example circuit schematic of a LISN were modified wires are represented by equivalent inductors.

FIG. 26 provides the values of various parameters used in equations (6) to (8).

### DETAILED DESCRIPTION

It should be understood at the outset that although illustrative implementations of one or more implementations are illustrated below, the disclosed systems and methods may be implemented using any number of techniques, whether currently known or not yet in existence. The disclosure should in no way be limited to the illustrative implementations, drawings, and techniques illustrated below, but may be modified within the scope of the appended claims along with their full scope of equivalents.

This specification describes the design of a single-phase, single-stage line impedance stabilization network (LISN) for medium-voltage (MV) applications. More than 1 kV rated wide-bandgap (WBG) power semiconductor switches are increasingly utilized in new, emerging power electronics energy systems to improve power density and efficiency. However, due to inherently fast-switching speeds, WBG switch modules emit considerable electromagnetic interference (EMI) (e.g., common mode or differential mode). There are standardized LISN solutions to validate and certify the new energy system for electromagnetic compatibility. However, most are for low voltage applications (i.e., <1 kV). MV LISNs (i.e., >1 kV) create challenges that do not exist in low voltage applications. This specification addresses such a technology gap. Specifically, a CISPR 16-1-2 compliant 50Ω/50 μH LISN with 1.5 kV, 75 A and 30 MHz measurement capability is described below. Detailed performance study versus non-linear parasitic parameters variations in MV inductors and capacitors is also described. Techniques to mitigate unwanted parasitic have are disclosed to develop the proposed LISN. A description of important LISN parameters is presented and factors influencing them are analyzed.

### Introduction

Fast-switching wide-bandap (WBG) semiconductors with extremely high dv/dt and di/dt can emit considerable conducted electromagnetic interference (EMI). This poses critical challenges in the conducted emissions (CE) and susceptibility assessments of WBG power electronics. Line impedance stabilization network (LISN) is the standardized device for repeatable CE tests, offering a constant source impedance to a device from 150 kHz to 30 MHz. It provides an essential isolation between the power source and devices under test. However, some example LISNs are rated for less than 1 kV, not more than 1 kV. A LISN may be used for electromagnetic compatibility (EMC). Substantial common mode (CM) and differential mode (DM) measurement deviations of >10 dB exist, resulting in certification failures when LISNs are not used. This impacts converter topologies. There are some LISNs with multiple stage analysis for 50 V systems. There are some LISN designs for up to 10 MHz. There are some hybrid LISN designs with low-pass and bandpass filters for a 230 V system. Before the technology describe below, there were no MV solutions for LISNs, hindering the EMC certification of modern energy systems.

Example WBG switch modules with high voltage ratings are increasingly applied to modern energy systems to innovate efficiency and power density. For these devices, identification of the worst-case EMI and formulation of preventive measures are mandatory to meet the EMC regulations. However, current industry practice often explores alternative but heuristic methods for EMC certification, primarily due to the limited availability of MV LISNs. Others have investigated the EMI of MV devices by measuring CM noises through current probes. While RF probes could be used to get insights, its results could considerably differ, which may not be sufficient to certify the >1 kV system effectively and reduces reproducibility of the results. Depending on aperture and placement of probes, the measured conducted EMI can vary when current probes are used. High-frequency capable MV LISNs are needed to facilitate EMC tests and integration of WBG technology into modern MV systems. Some LISNs are rated for high current applications, but they are limited to 1 kV measurements and cannot meet the need for EMC certification tests of >1 kV systems. Furthermore, characterization process of high-frequency LISN specifications and the factors affecting them are not analyzed in the technical documents of such products. This specification describes solutions for these gaps by addressing the challenges in designing a LISN device with high power and high frequency measurement capabilities as well as proposes scalable mitigation techniques for these challenges.

In terms of achieving high voltage and frequency measurement capabilities for a LISN targeting MV applications, some challenges can come from its >1 kV rated passive elements. As parasitic parameters are directly coupled with physical size, a larger package to achieve higher voltage can have an impact. Inductors play a vital role in LISNs, as it passes low-frequency signals while isolating a device under test (DUT) from sources at high frequencies. However, its parasitic parameters (e.g., turn-to-turn or turn-to-core capacitance) can limit a LISN's high-frequency measurement, leading to unexpected, nonlinear capacitive behaviors. Similarly, capacitors' equivalent series inductance (ESL) could significantly limit a LISN's high-frequency performance and insertion voltage gain, resulting in inductive behavior at higher frequencies by internal resonances. Similar to EMI filters, such effects can substantially hinder LISN's isolation and high-frequency noise coupling capabilities, jeopardizing EMC accuracy. However, inherent parasitic parameters of the LISN elements and their effects on LISN functionality are relatively unknown. The effects of inductor parasitic capacitance (CP) and capacitor's equivalent series resistance (ESR) on the LISN impedance and stability may be known, the effects of capacitor ESL may be unknown. Additionally, the effects of such parasitic elements on LISN isolation, noise coupling and impedance phase may be unknown. Thorough modeling, characterization, and mitigations of parasitic parameters range become crucial in LISN development for high power ratings. This specification aims to address this knowledge gap by exploring the impact of each LISN component's parasitic parameters on its functionality in details.

This specification proposes a single-stage 1.5 kV, 75 A, and 30 MHz MV LISN for the CE compliance tests (i.e., CISPR 16-1-2). Table 1 summarizes the basic parameters of the proposed LISN. The design does not require a multistage configuration and eliminates the need for extra passive elements. A comprehensive parasitic analysis and its impact on LISN functionality is analyzed. Methods to mitigate ESL in high voltage capacitors are described below and use the mutual inductances of the PCB traces. The proposed method does not solely rely on parallel combination of extra capacitors, thus eliminating the possibility of antiresonance issues and parameter matching constraints. Then, MV inductor design is explored to suppress parasitic parameters and resonance. Proposed design methods can be scaled to achieve higher current ratings and power ratings. Simulation and experimental studies are done to validate the effectiveness of proposed LISN in isolation, high-frequency noise coupling, and source impedance stability. CM EMI measurement capabilities are compared with an example 620 V LISN. Greater than 1 kV CM EMI measurement results are described to demonstrate MV capabilities of proposed LISN.

TABLE 1
Parameters of proposed MV LISN

| Parameter | Specification |
|---|---|
| Topology | Single-phase, Single-stage, V-type |
| Type | 50 Ω/50 μH (CISPR 16-1-2) |
| Dc Voltage Rating | 1.5 kV |
| Current Rating | 75 A |
| Frequency Range | 150 kHz-30 MHz |

The rest of this specification is organized as follows. A second section discusses the new LISN challenges in MV and high-frequency applications. A third section provides a simulation study to explore the impact of parasitic parameters on LISN functionality. A fourth section offers strategies to mitigate the parasitic parameters of inductors and capacitors.

### Medium Voltage LISN and Design Challenges

### A. Example LISN

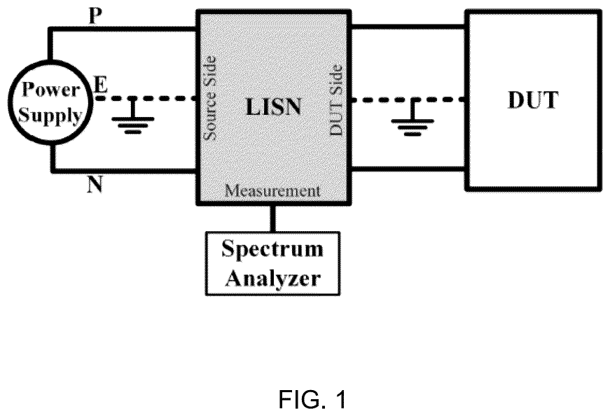

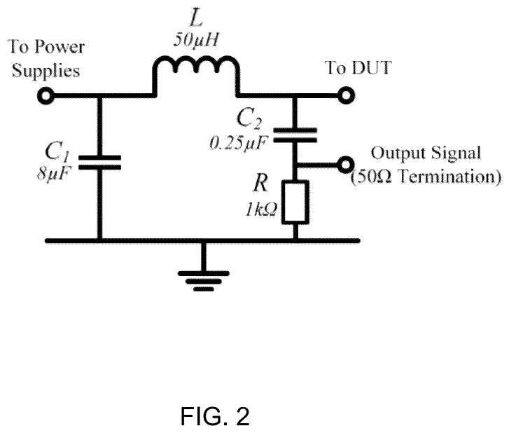

LISNs are widely used to measure conducted EMI emissions. However, its design strategy may not have been shared except for standard guidelines. In some implementations, it is inserted between the power mains and the DUT, as shown in FIG. 1. It is a passive network that isolates the test system with a reference impedance and provides a measurement point. FIG. 2 shows an ideal 50 μH/50Ω LISN (i.e., no parasitic parameters) with standard values specified in CISPR 16-1-2 for 150 KHz-30 MHz. The input is connected to mains, while capacitor (C₁) and inductor (L) form a low-pass second-order filter to prevent the high-frequency noise from a source from compromising measurements. It also prevents noise from DUT from propagating back to the mains. The capacitor (C₂) and resistor (R) constitute a high-pass filter to couple the emissions from the DUT to a connector at the test receiver port. This allows LISN to function as a high-pass filter with a cut-off frequency of about 150 kHz. The high-frequency noise is coupled to an output port. Then, the measurement devices (e.g., a spectrum analyzer) are used to monitor the emissions with a 50Ω input impedance.

Table 2 shows the specifications of some example LISNs. Many example LISNs are developed for <1 kV applications. MV LISN study and fabrication is rare, and their characterization process in high frequency is relatively unknown. This presents considerable EMC certification challenges in the emerging system with MV WBG switches.

TABLE 2
Example LISN specifications

| | DC Voltage Rating | Frequency Range |
|---|---|---|
| Com-Power LI- | 620 V | 150 kHz-30 MHz |
| 1100C | | |
| Schwarzbeck | 1000 V | 150 kHz-30 MHz |
| NNLK8129-2 | | |
| Tekbox TBL50100-1 | 250 V | 150 kHz-30 MHz |

### B. Challenges in MV LISN Design

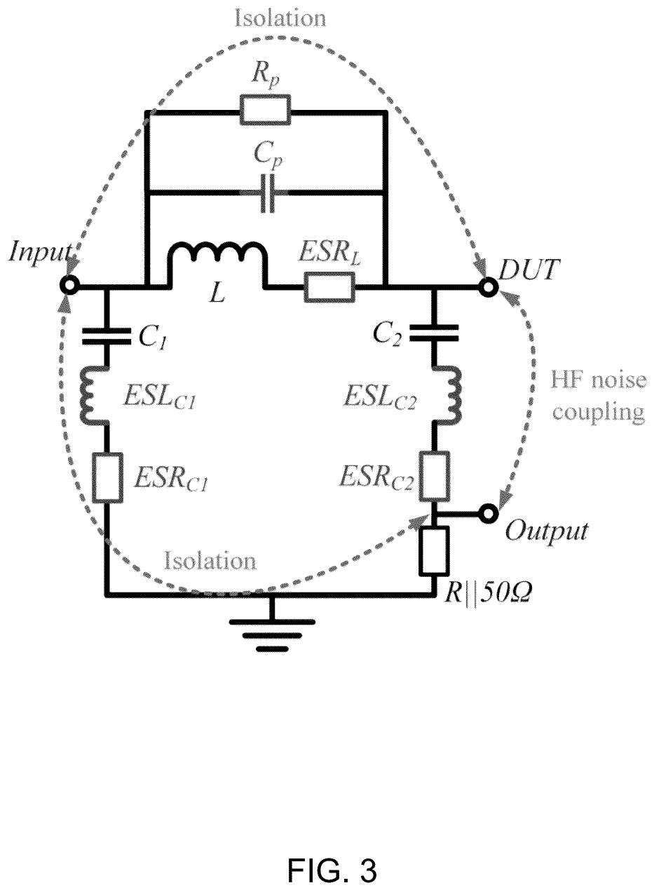

To ensure measurement fidelity, it is critical to understand the high-frequency characteristics of the passive components of a LISN. L and C₂ are pivotal in maintaining stable LISN operations and effectively coupling high-frequency noise to the receiver, while C₁ plays important role in providing the isolation from the source. C₂ is particularly important as it is on the direct shunt path that couples the noise from the DUT to the measurement port. FIG. 3 shows the effective LISN schematic highlighting the parasitic parameters of its components and its terminals. ESL_{C1} and ESL_{C2} are ESL of C₁ and C₂, while ESR_{C1} and ESR_{C2} represents the ESR of both capacitors. The high frequency model of an inductor includes parasitic capacitance (C_{P}), series parasitic resistance (ESR_{L}) and parallel parasitic resistance (R_{P}). The behavior of this circuit can largely deviate from the ideal LISN in FIG. 2 at high frequencies, specifically due to ESL_{C2}, C_{P}, and ESL_{C1}.

An MV inductor can increasingly behave capacitively at high frequency due to CP dominance (i.e., interwinding capacitances between the winding turns). Thus, it could significantly alter the impedance beyond the self-resonant frequency (SRF). Similarly, an MV film capacitor increasingly behaves nonlinearly due to high ESL. The ESL causes a substantial deviation in impedance characteristics beyond SRF, which poses a significant challenge. Additionally, MV elements have relatively larger physical dimensions; this inherently makes MV inductors and capacitors have non-negligible parasitic elements. This can be observed in Tables 3 and 4, where 0.22 μF capacitors and 50 μH inductors have nonlinear parasitic parameters at various voltage ratings. The 1.5 kV rated inductors and capacitors show 50% to 100% higher parasitic than 0.5 kV ones. Particularly, typical ESL values of several nanohenries can cause significant resonances within the specified 30 MHz range for conducted EMI.

TABLE 3
Experimentally measured parasitic values
of example 0.22 μF film capacitors

| | Voltage Rating | ESL |
|---|---|---|
| Manufacturer 1 | 500 V | 27 nH |
| | 1500 V | 58 nH |
| Manufacturer 2 | 500 V | 33 nH |
| | 1500 V | 69 nH |
| Manufacturer 3 | 500 V | 41 nH |
| | 1500 V | 76 nH |

TABLE 4
Experimentally measured parasitic
values of example 50 uH inductors

| | Voltage Rating | C_{P} |
|---|---|---|
| Manufacturer 1 | 500 V | 33 pF |
| | 1500 V | 57 pF |
| Manufacturer 2 | 500 V | 41 pF |
| | 1500 V | 73 pF |
| Manufacturer 3 | 500 V | 30 pF |
| | 1500 V | 56 pF |

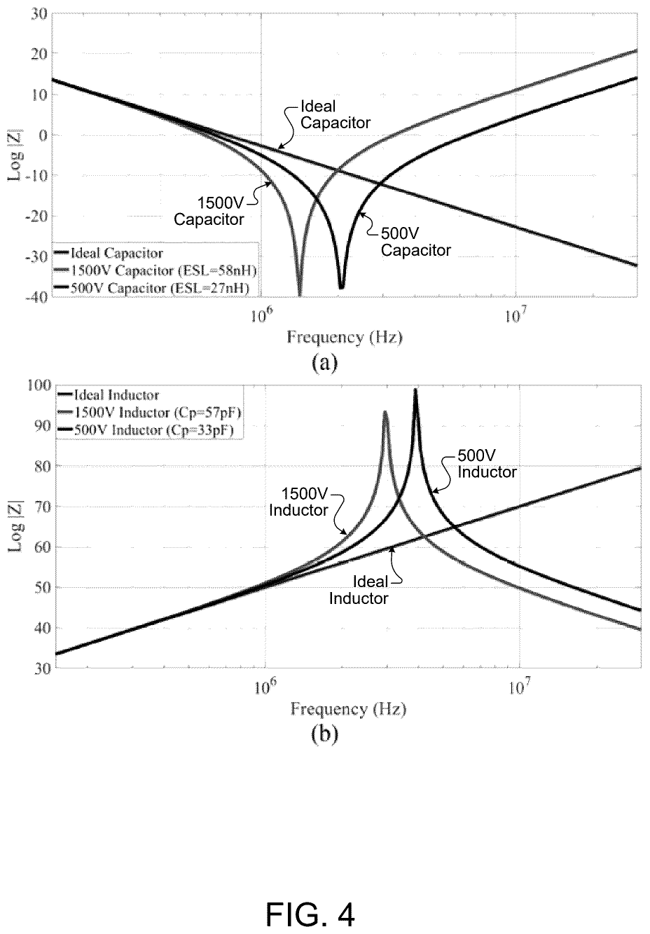

The impact can be experimentally observed in FIG. 4, where the impedance of the example components is compared to ideal components. Due to larger C_{P} and ESL, 1.5 kV inductors and capacitors have much lower SRF than lower voltage counterparts. This means using various passive components without proper parasitic mitigation techniques can significantly alter MV LISN operations at high frequency.

### Effect of Parasitic Elements on MV LISN

The parasitic parameters' impact on LISN can be understood by analyzing its impedance and transfer function.

### A. Impedance Characteristics

A LISN must offer repeatable and consistent EMI measurement with a constant 50Ω source impedance (Z_{LISN}) to the DUT, with specific phase requirements. By assuming the power supply side is shorted and ideal components are used (i.e., no parasitic parameters), Z_{LISN} in FIG. 2. can be analyzed where R₅₀=50Ω is the termination impedance of the noise measurement device. According to CISPR 16-1-2 limits, Z_{LISN} magnitude and phase must be within specified limits.

By assuming nonideal conditions, the parasitic parameters, C_{P} and ESL_{C2} depicted in FIG. 3 could be integrated into equation (1). Then, its impact on the Z_{LISN} can be re-derived as follows:

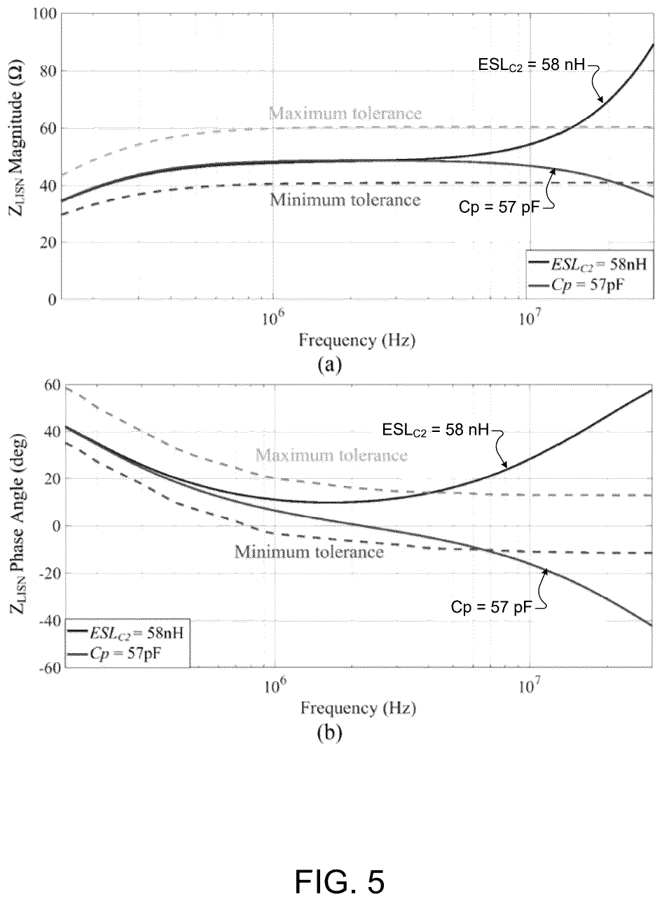

As observed in equation (2), C_{P} and ESL_{C2} introduce multiple higher order terms in both numerator and denominator, which are not present in Z_{LISN} in equation (1). This could cause LISN impedance to deviate from its standard at high frequency with unwanted resonances. It can be observed in FIG. 5 in comparison with the CISPR 16-1-2 specified limits. To explore real-world impacts, C_{P} and ESL_{C2} are assumed 57 pF and 58 nH, respectively, in this simulation from the experimental measurement of 1.5 kV products. It may be apparent that due to C_{P} and ESL_{C2}, both Z_{LISN} magnitude and phase exceed the CISPR 16-1-2 limits at high frequency.

$$\begin{matrix}\begin{matrix}{Z}_{LISN} = sL ‖ [ \frac{1}{{sC}_{2}} + ( R \vert \vert {R}_{50} ) ] \\ = \frac{{s}^{2} {LC}_{2} ( R \vert \vert {R}_{50} ) + sL}{{s}^{2} {LC}_{2} + {sC}_{2} ( R \vert \vert {R}_{50} ) + 1}\end{matrix} & ( 1 ) \\ \begin{matrix}{Z}_{{LISN}_{\text{?}}} = [ sL \vert \vert \frac{1}{{sC}_{P}} ] \vert \vert [ ( \frac{1}{{sC}_{2}} + {sESL}_{C 2} ) + ( R \vert \vert {R}_{00} ) ] \\ = \frac{{s}^{3} {LC}_{2} {ESL}_{C 2} + {s}^{2} {LC}_{2} ( R \vert \vert {R}_{50} ) + sL}{\begin{matrix}{s}^{4} {LC}_{P} {C}_{2} {ESL}_{C 2} + {s}^{3} {LC}_{P} {C}_{2} ( R \vert \vert {R}_{50} ) + \\ {s}^{2} ( {LC}_{2} + {LC}_{p} + {ESL}_{C 2} {C}_{2} ) + {sC}_{2} ( R \vert \vert {R}_{50} ) + 1\end{matrix}} .\end{matrix} \\ \text{?} \text{indicates text missing or illegible when filed} & ( 2 )\end{matrix}$$

### B. Noise Coupling and Isolations

In accordance with CISPR 16-1-2, a LISN must have well-defined insertion loss characteristics between its designated terminals. As depicted in FIG. 3, these terminals comprise: 1) the power supply terminal, 2) DUT terminal, where the DUT is connected, and 3) the output signal port, where the conducted emissions are measured. A parameter for proper noise coupling is defined as voltage division factor (VDF).

Additionally, the isolation characteristics between the input terminals feeding the receiver and the DUT port are quantified by the decoupling factors (DFₒᵤₜ and DF_{DUT}, respectively). Assuming ideal passive components within the LISN, these parameters can be mathematically expressed in equations (3) to (5).

$$\begin{matrix}\begin{matrix}VDF = 20 log \vert \frac{{V}_{out}}{{V}_{DUT}} \vert \\ = 20 log \vert \frac{{sC}_{2} ( R \vert \vert {R}_{50} )}{{sC}_{2} ( R \vert \vert {R}_{50} ) + 1} \vert\end{matrix} & ( 3 ) \\ \begin{matrix}{DF}_{out} = 20 log \vert \frac{{V}_{out}}{{V}_{i n}} \vert \\ = 20 log \vert \frac{{sC}_{2} ( R \vert \vert {R}_{50} )}{{s}^{3} {LC}_{1} {C}_{2} ( R \vert \vert {R}_{50} ) + {s}^{2} {LC}_{2} + {sC}_{1} ( R \vert \vert {R}_{50} ) + 1} \vert\end{matrix} & ( 4 ) \\ \begin{matrix}{DF}_{DUT} = 20 log \vert \frac{{V}_{DUT}}{{V}_{i n}} \vert \\ = 20 log \vert \frac{{sC}_{2} ( R \vert \vert {R}_{50} ) + 1}{{s}^{3} {LC}_{1} {C}_{2} ( R \vert \vert {R}_{50} ) + {s}^{2} {LC}_{2} + {sC}_{2} ( R \vert \vert {R}_{50} ) ] + 1} \vert\end{matrix} & ( 5 )\end{matrix}$$

VDF presented in equation (3) presents a high-pass filter for the conducted emissions flowing from DUT to the output port. DFₒᵤₜ presented in equation (4) has bandpass filter characteristics and presents the isolation between the output port and input terminal. DF_{DUT} presented in equation (5) ideally exhibits low-pass filter characteristics for isolation between DUT and input. Similar to Z_{LISN}, these parameters are also susceptible to parasitic parameters. While VDF is affected by ESL_{C2} only, DFₒᵤₜ and DF_{DUT} are affected by C_{P} and ESL of both LISN capacitors. To explore this, equations (3) to (5) has been rederived with parasitic impact.

$$\begin{matrix}\begin{matrix}{VDF}^{′} = 20 log \vert \frac{{V}_{out}}{{V}_{DUT}} \vert \\ = 20 log \vert \frac{{a}_{1} s}{{b}_{2} {s}^{2} + {b}_{1} s + 1} \vert\end{matrix} & ( 6 ) \\ \begin{matrix}{DF}_{out}^{′} = 20 log \vert \frac{{V}_{out}}{{V}_{i n}} \vert \\ = 20 log \vert \frac{{c}_{5} {s}^{5} + {c}_{3} {s}^{3} + {c}_{1} s}{{d}_{5} {s}^{5} + {d}_{5} {s}^{5} + {d}_{4} {s}^{4} + {d}_{3} {s}^{3} + {d}_{2} {s}^{2} + {d}_{1} s + 1} \vert\end{matrix} & ( 7 ) \\ \begin{matrix}{DF}_{DUT}^{′} = 20 log \vert \frac{{V}_{DUT}}{{V}_{i n}} \vert \\ = 20 log \vert \frac{{e}_{4} {s}^{4} + {e}_{3} {s}^{3} + {s}_{2} {s}^{2}}{{f}_{6} {s}^{6} + {f}_{5} {s}^{5} + {f}_{4} {s}^{4} + {f}_{3} {s}^{3} + {f}_{2} {s}^{2} + {f}_{1} s + 1} \vert\end{matrix} & ( 8 )\end{matrix}$$

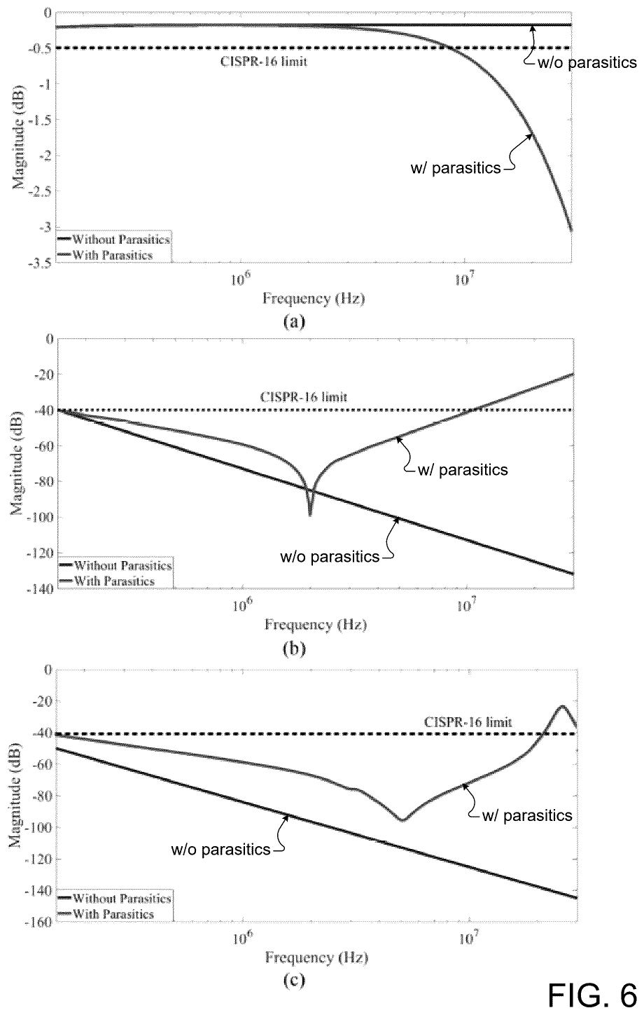

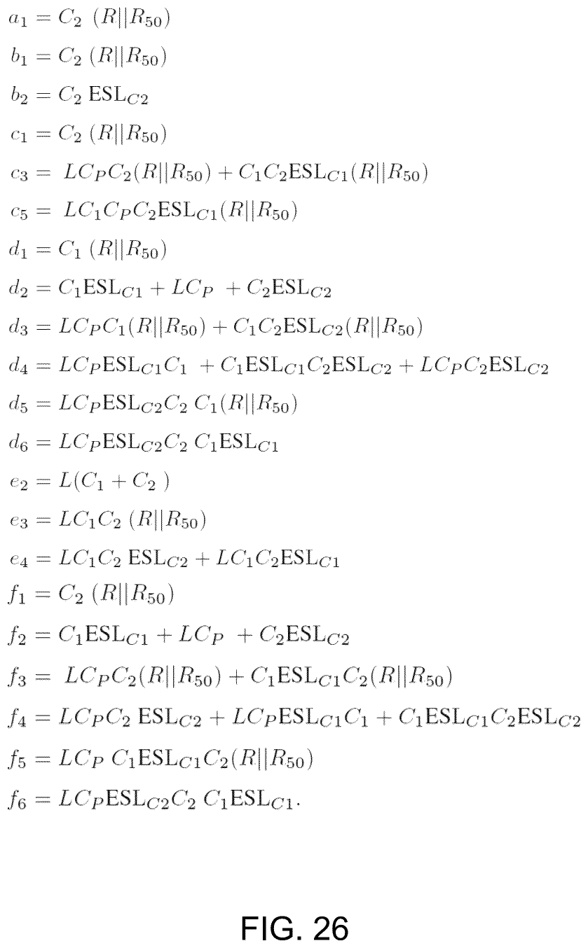

In equations (6) to (8), aᵢ, bᵢ, cᵢ, dᵢ, eᵢ, and fᵢ are the functions of the circuit parameters, including C_{P} and ESL of both capacitors (details are shown in the FIG. 26). As analyzed in equations (6) to (8), C_{P} and both ESL introduce several higher order poles and zeros, which do not exist in ideal cases. Thus, this can alter LISN efficiency at high frequencies. This is demonstrated in FIG. 6 where comparative bode gain plots with and without the parasitic parameters are presented. To understand the real-world impact, in these simulations ESL_{C2}, C_{P}, and ESL_{C1} are assumed 58 nH, 57 pF, and 50 nH, respectively. Part (a) of FIG. 6 depicts VDF with and without ESL_{C2}. Integrating ESL_{C2} into the analysis attenuates high-frequency noise coupling, as VDF deviates from the desired high-pass filter characteristics and exceeds the CISPR-16 limit of <0.5 dB. This may hinder the high-frequency noise measurements of LISN, compromising accuracy. Parts (b) and (c) of FIG. 6 show how C_{P} and both ESL can introduce unwanted resonances and gain increase in DFₒᵤₜ and DF_{DUT}, reducing isolations from the input terminals to noise measurement port and DUT, violating the specified >40 dB CISPR-16 limit for both parameters. These effects will allow the high-frequency noise from a DUT to flow back to the source and vice versa. These effects necessitate new effective parasitic mitigation for CISPR-16 compliance of proposed LISN.

The effects of the parasitic elements on different LISN parameters are summarized in Table 5.

TABLE 5
Effect of parasitic elements on LISN parameters

| LISN Parameters | Influencing Parasitic Element |
|---|---|
| Z_{LISN} (magnitude and phase) | ESL_{C2} and C_{P} |
| VDF (noise coupling) | ESL_{C2} |
| DFₒᵤₜ (isolation) | ESL_{C2}, C_{P}, and ESL_{C1} |
| DF_{DUT} (isolation) | ESL_{C2}, C_{P}, and ESL_{C1} |

### Proposed LISN Design and Parasitic Parameter Minimization

### A. Parasitic Parameter Constraints for Proposed LISN Design

As presented in Table 5, ESL_{C2} and C_{P} affect all or nearly all major LISN operational parameters, while ESL_{C1} affects DFₒᵤₜ and DF_{DUT}. Comprehensive parametric analyses have been performed to derive specific constraints regarding the ESL_{C2}, C_{P}, and ESL_{C1} values for the proposed LISN considering independent effects of each parasitic parameter.

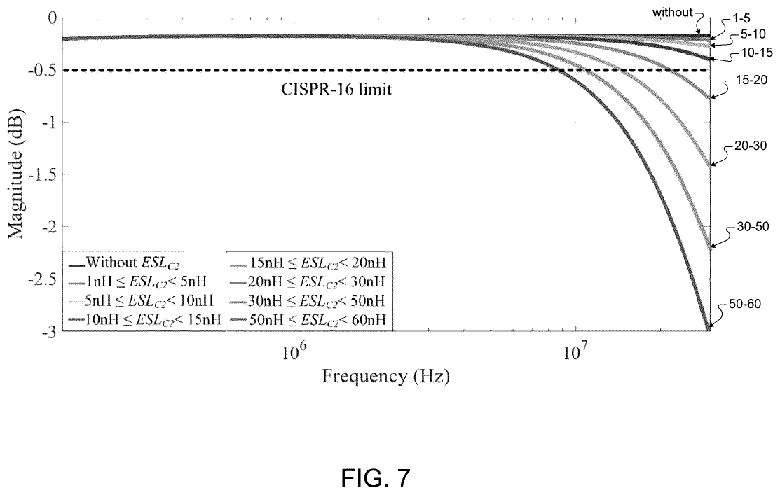

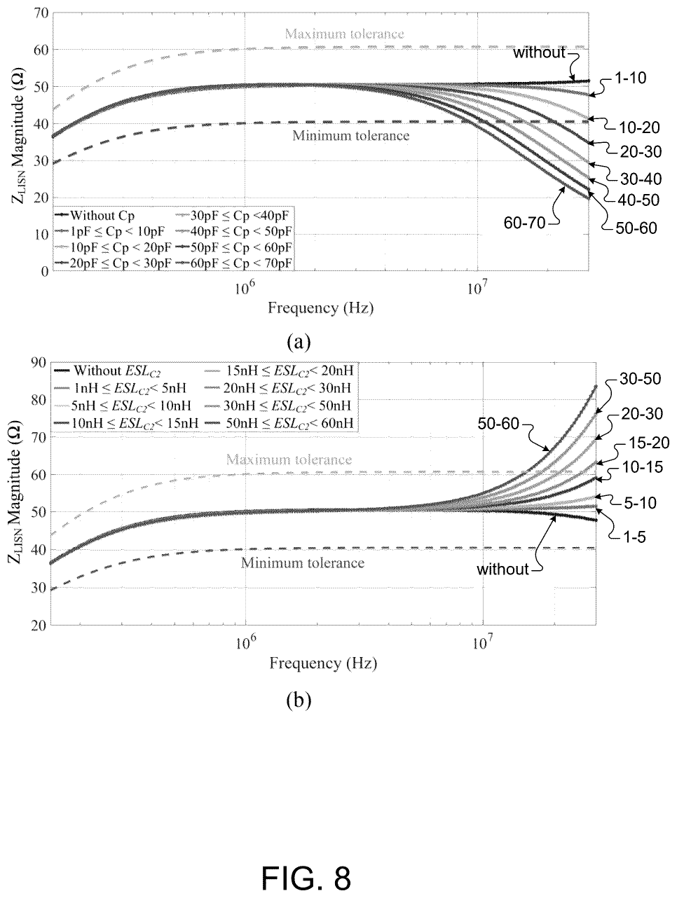

First, FIG. 7 presents the VDF parametric sweep analysis for different ESL_{C2} values using equation (6). It can be observed that for ESL_{C2} values less than 15 nH, VDF stays within CISPR-16 specified limit. Then, parametric simulation analysis has been performed for Z_{LISN} magnitude using equation (2) by varying the C_{P} values and maintaining ESL_{C2} within the 15 nH constraint. As evident from part (a) of FIG. 8, the Z_{LISN} magnitude remains compliant with the CISPR 16-1-2 specified limits for C_{P} values below 20 pF. Additionally, in part (b) of FIG. 8, Z_{LISN} magnitude variation is presented for different ESL_{C2} values when C_{P} is restricted below 20 pF. It is apparent that for ESL_{C2} values less than 15 nH, Z_{LISN} magnitude adheres to the CISPR 16-1-2 specified tolerances, which matches the VDF sweep analysis for ESL_{C2}. Consequently, ESL_{C2}<15 nH and C_{P}<20 pF are established as design constraints for the proposed LISN.

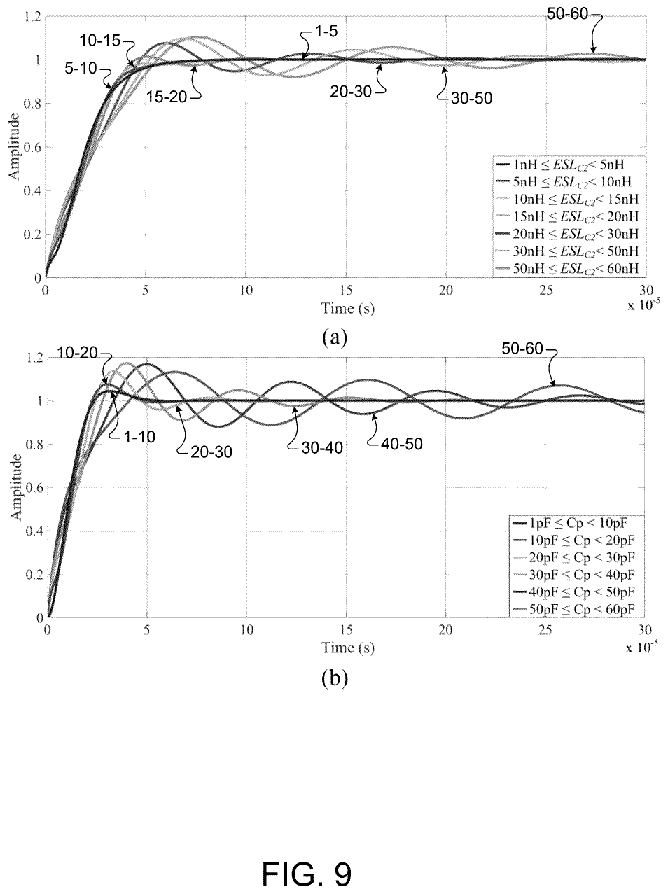

The step response analysis presented in FIG. 9 validates these constraints. In part (a) of FIG. 9, step responses for different ranges of ESL_{C2} values are presented. It is observed that for ESL_{C2} values<15 nH, a stable, nonoscillatory step response is achievable, similar to the observations from VDF and Z_{LISN} analysis. In case of C_{P} and as illustrated in part (b) of FIG. 9, the threshold value to attain a step response with acceptable overshoot and settling time is found to be less than 20 pF, aligning with the previous C_{P} analysis conclusions.

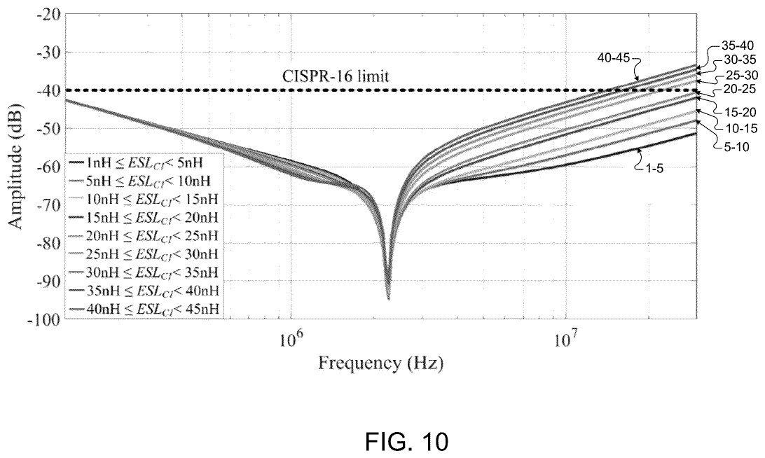

Finally, FIG. 10 presents the parametric analysis of DFₒᵤₜ for different values of ESL_{C1}, while maintaining ESL_{C2} and C_{P} below 15 nH and 20 pF, respectively. The analysis reveals that for ESL_{C1} values less than 25 nH, DFₒᵤₜ satisfies the CISPR-16 standard.

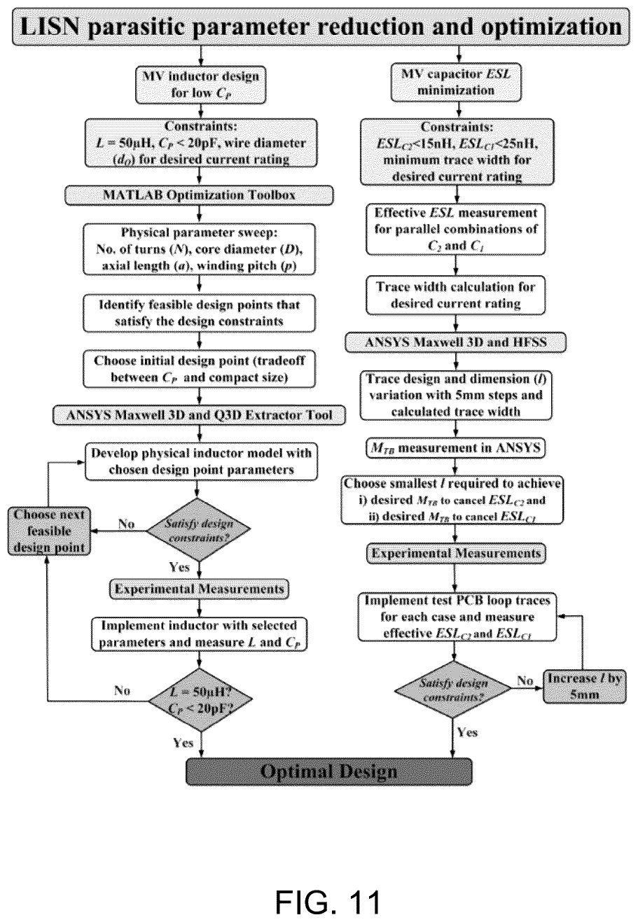

Based on these parametric analyses, specific design objectives are set for the proposed LISN in terms of ESL_{C2}, C_{P}, and ESL_{C1} values. Furthermore, to ensure adherence to CISPR 16-1-2 limits, the standard specified impedance characteristics, insertion loss and isolation characteristics are taken into consideration. Table 6 summarizes these design goals and considerations. The proposed approach of parasitic parameter minimization and optimization will systematically achieve the design goals, as illustrated in FIG. 11.

TABLE 6
Design objectives for proposed LISN according to CISPR 16-1-2

| Parameter | Specification | |
|---|---|---|
| ESL_{C2} | <15 | nH |
| C_{P} | <20 | pF |
| ESL_{C1} | <25 | nH |
| Z_{LISN} Magnitude | (50 μH + 50 Ω) ± 20% (150 kHz-30 MHz) | |
| Z_{LISN} Phase | Nominal phase angle ± 11.5° (150 kHz- | |
| | 30 MHz) | |
| VDF (DUT to receiver) | <0.5 dB | (150 kHz-30 MHz) |
| DFₒᵤₜ (Mains to receiver) | >40 dB | (150 kHz-30 MHz) |
| DF_{DUT} (Mains to DUT) | >40 dB | (150 kHz-30 MHz) |

### B. MV Capacitor ESL Minimization

1) Approach #1. Parallel MV Capacitors: Multiple parallel capacitors may reduce the overall ESL while achieving the same capacitance. An experimental study has been done to quantify ESL_{C1} and ESL_{C2} in diverse configurations. Two separate case studies are discussed below. Each is implemented on test PCB boards, incorporating a shunt path identical to a LISN. The signal traces measured 100 mm in length and 12 mm in thickness, with Bayonet Neill-Concelman (BNC) connectors at both ends. A network analyzer measures the impedance of the capacitor shunt path.

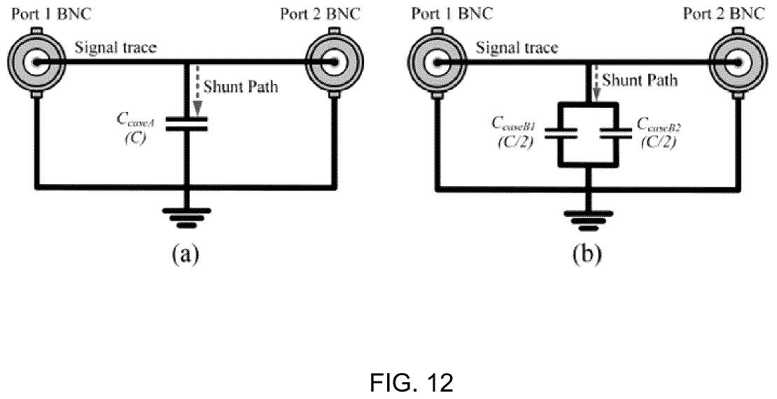

Case-A: To assess ESL_{C2}, a single 0.22 μF film MV capacitor is implemented as illustrated in part (a) of FIG. 12. Measured impedance exhibits a 1.95 MHz resonant frequency with an approximate 30 nH ESL_{C2}, significantly larger than the target in Table 6. Thus, it is may not be viable. Similarly, to assess ESL_{C1}, a single 8 μF MV capacitor is implemented. The measured SRF is found at 256 kHz, with an approximate ESL_{C1} at around 48 nH. This also may not meet the design goals specified in Table 6.

Case-B: To assess ESL_{C2}, two parallel 0.11 μF capacitors are used to achieve a similar net capacitance to Case-A as illustrated in part (b) of FIG. 12. It has an increased resonant frequency of 2.67 MHZ, corresponding to an effective ESL_{C2} of 18 nH; this may not meet the required <15 nH goal. Similarly, two parallel 4 μF capacitors are implemented to assess ESL_{C1}. Although the SRF increases to 331 kHz (ESL_{C1}=29 nH), this may not meet the required <25 nH goal for ESL_{C1}.

2) Approach #2. Negative Mutual Inductance of Coupled PCB Traces: As shown in cases A and B, the parasitic reduction to meet the target in Table 6 may not be possible unless more than two parallel capacitors are used. Furthermore, utilizing the right combinations to have the same capacitance could be challenging due to possible antiresonance effects. An increased number of capacitors could complicate the design of this sensitive device, as parameter matching for paralleled capacitors becomes mandatory to achieve desired ESL reduction. The need for extra capacitors has been compensated by utilizing coupled PCB traces.

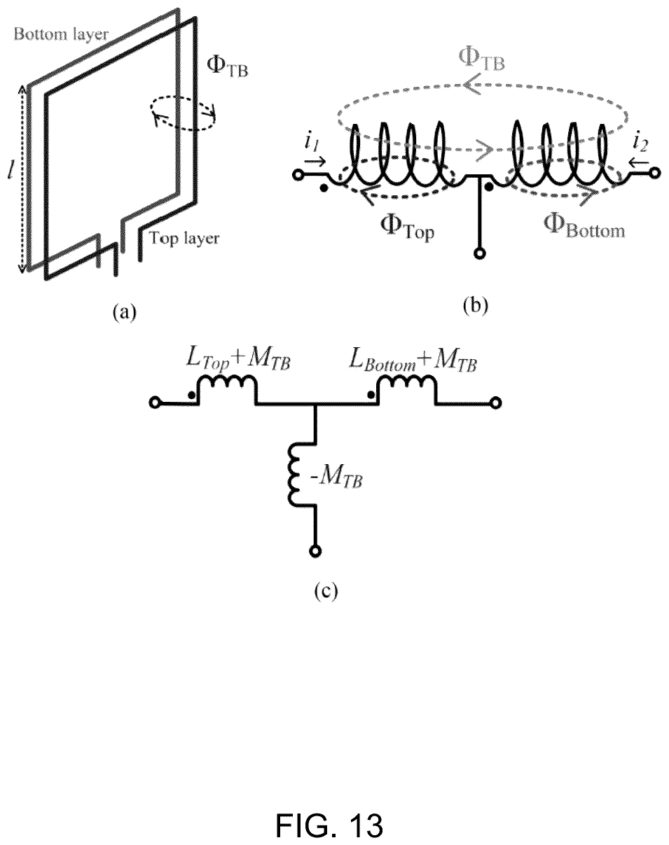

A mutual inductance between two vertically stacked square PCB traces are shown in part (a) of FIG. 13. The negative mutual inductance between these traces can be used to reduce MV capacitor's ESL. Specifically, two PCB traces strategically positioned on top and bottom layers to form an equivalent center-tapped coupled magnetic winding structure, as shown in part (b) of FIG. 13. ϕTop and ϕBottom are the magnetic fluxes for the top and bottom layers, respectively. ϕTB is the mutual coupling of the magnetic fluxes, while i₁ and i₂ are the currents in opposite directions. This structure creates opposing mutually coupled magnetic fields between traces and results in a small negative mutual inductance in the shunt path (M_{TB}). Careful design optimization of coupled PCB traces can create an appropriate amount of negative mutual inductance −M_{TB}. The coupled square PCB traces can be printed on a PCB board. Thus, it can be utilized for ESL_{C2} and ESL_{C1} reduction. The inductance matrix for the system in FIG. 13(b) could be described in equation (9).

$$[ \begin{matrix}{Φ}_{Top} \\ {Φ}_{Bottom}\end{matrix} ] = [ \begin{matrix}{L}_{Top} & - {M}_{TB} \\ - {M}_{TB} & {L}_{Bottom}\end{matrix} ] [ \begin{matrix}{i}_{1} \\ {i}_{2}\end{matrix} ] . \qquad ( 9 )$$

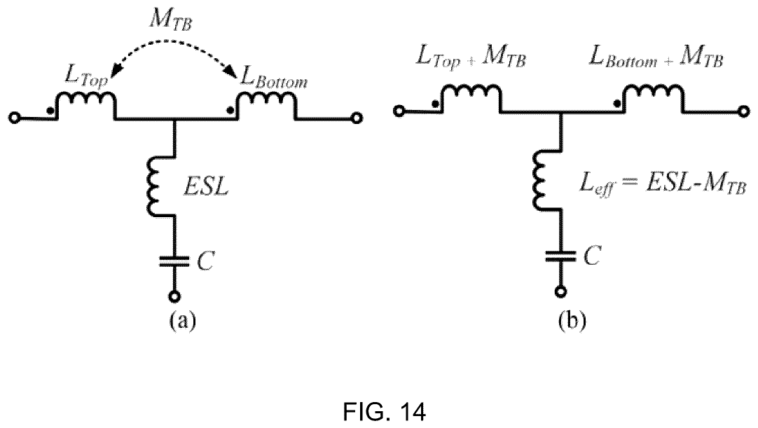

The equivalent T-model of the center-tapped structure is shown in part (c) of FIG. 13, where L_{Top} and L_{Bottom} are the self-inductances for the top and bottom layer loops. This results in M_{TB}≤(L_{Top}·L_{Bottom})\hat{ }(1/2). The inductance of a square loop can be obtained using equation (10), where l, y, and n are the trace length, trace radius, and number of turns of the square loops, respectively. This negative inductance on the shunt path of the MV capacitors can result in an overall reduction of ESL, as L_{eff}=ESL−M_{TB}, as shown in FIG. 14.

$${L}_{top} = {L}_{bottom} = \frac{2 {μ}_{0} {n}^{2} l}{π} [ ln ( \frac{l}{y} ) - 0.774 ] \qquad ( 10 )$$

Case-C: The coupled PCB traces can be implemented in combination with two parallel capacitors for both C₁ and C₂. Through the optimization process in FIG. 11, it has been identified that the traces with M_{TB} of ˜18 nH on the shunt path could reduce the ESL_{C2} below 15 nH, while an M_{TB} of ˜29 nH can get ESL_{C1} to below 25 nH, achieving the goal in Table 6.

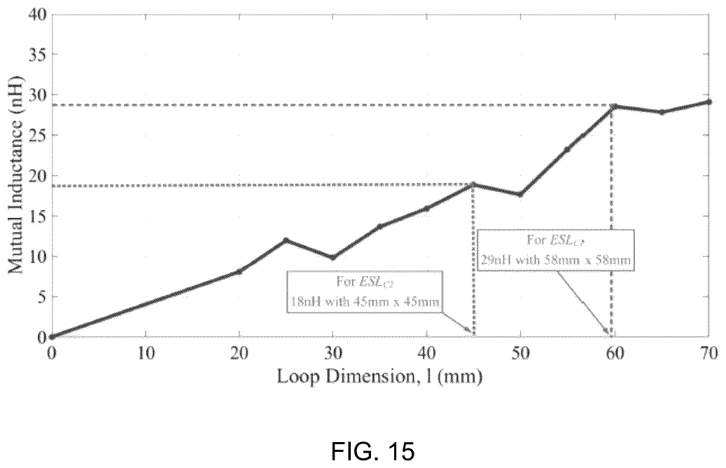

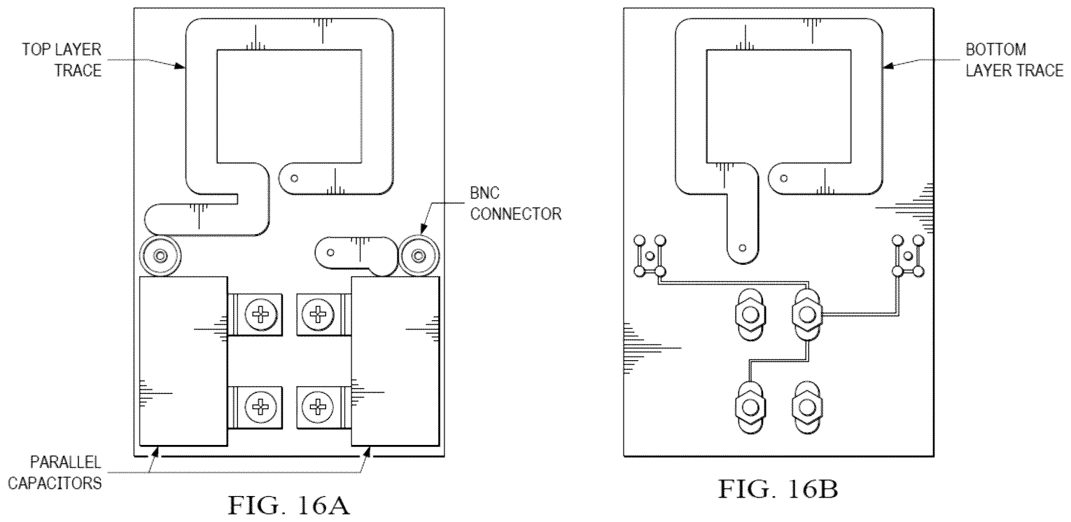

To achieve a current rating of 75 A for the proposed LISN, at least 11.5 mm trace width may be used according to the IPC-2152 (Institute of Printed Circuits) standards. This will allow a 75° C. temperature variation with a trace thickness of 0.8 mm. In some implementations, a 12 mm trace width is chosen for the PCB traces. Then, the square loop dimensions (l) necessary to achieve necessary M_{TB} to cancel ESL_{C2} and ESL_{C1} can be derived. FIG. 15 shows the M_{TB} variation with different trace loop dimensions from simulations when the trace width is 12 mm. It shows that a loop dimension of l=45 mm yields approximately 18 nH M_{TB}, while l=58 mm is needed for 29 nH M_{TB}. Based on those results, 45 mm×45 mm and 58 mm×58 mm loop dimensions are chosen for ESL_{C2} and ESL_{C1} cancellation loop traces, respectively. With these dimensions, in case of ESL_{C2} cancellation L_{Top} and L_{Bottom} are found to be 41.28 nH and 45.4 nH, respectively from simulations, with a mutual coupling coefficient of 0.43. In the case ESL_{C1} cancellation traces L_{Top}, L_{Bottom} and mutual coupling coefficient are found to be 60.23 nH, 59.73 nH, and 0.48, respectively.

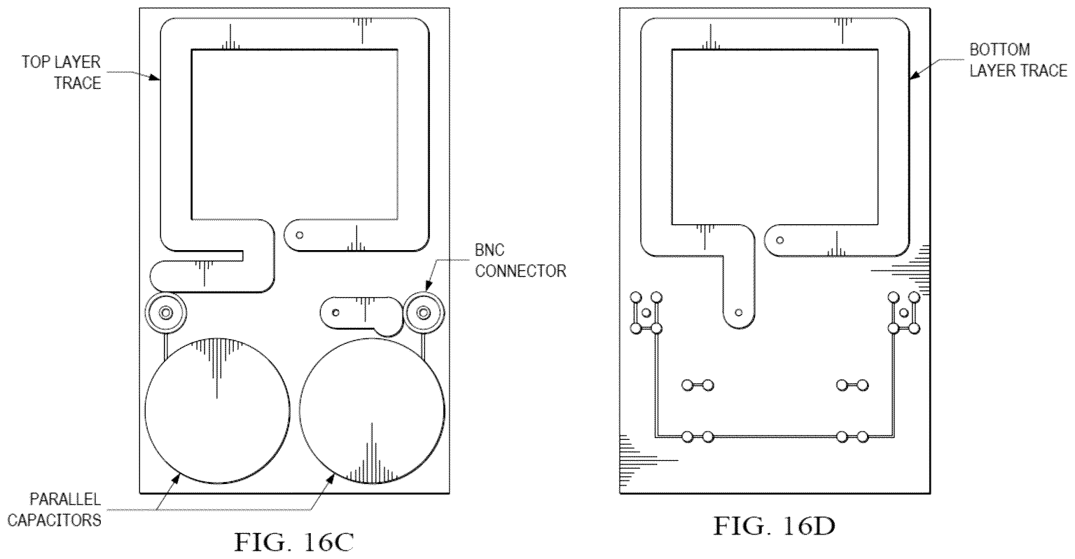

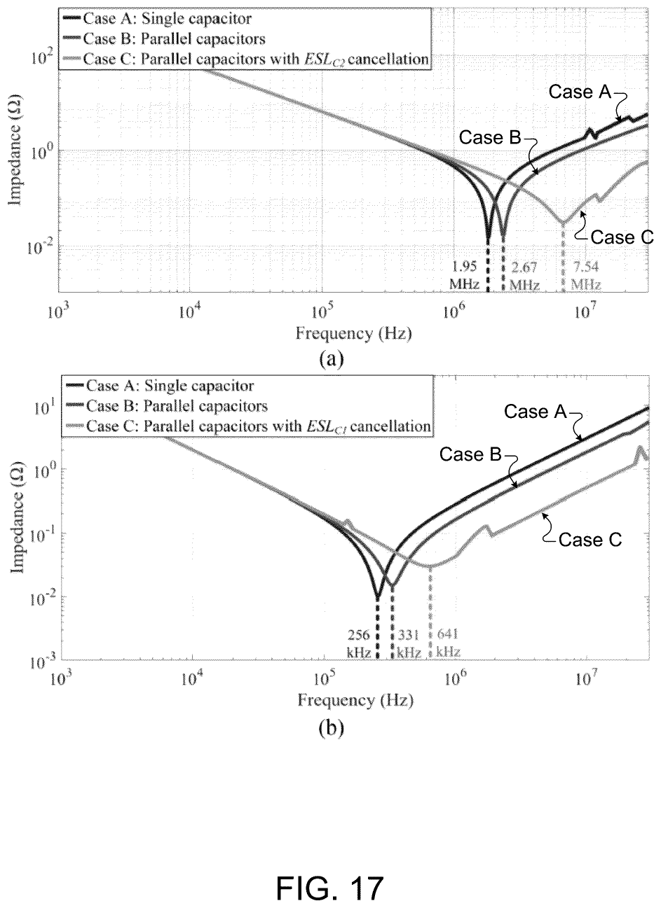

3) Experimental Implementation and Validation of ESL Minimization: Based on simulations, 45 mm×45 mm and 58 mm×58 mm square trace loops with a width of 12 mm are implemented on the PCB with two parallel capacitors for ESL_{C2} and ESL_{C1} cancellation, respectively. They are shown in FIG. 16. FIG. 17 shows the measured impedances for all cases. Notably, the implementation of coupled PCB traces in conjunction with parallel capacitors enhances the high-frequency performance of the shunt path. In terms of ESL_{C2} cancellation, in part (a) of FIG. 17 it shows that SRF increases to approximately 7.54 MHz. This translates to an effective reduction in ESL_{C2} to a value of 2.18 nH within the shunt branch. Similarly, for ESL_{C1} cancellation, a significant rise in SRF to 641 kHz is observed in part (b) of FIG. 17, corresponding to an effective ESL_{C1} of 7.71 nH. It is apparent that it is lower than those observed in the other two cases. This observation aligns with the established ESL design goals outlined in Table 6. Consequently, case C offers one of the solutions for achieving high-frequency noise coupling, isolation characteristics, and overall impedance behavior within the LISN.

Furthermore, the minimum of impedances remains almost flat due to a noticeably reduced ESL, leaving ESR as the only dominant parameter influencing the shunt path of both C₂ and C₁. These features overcome the capacitor science limitations in developing MV LISN (i.e., high parasitic parameters).

### C. MV Inductor Design for Low C_{P}

1) MV Inductor Parameter Optimization for Low C_{P}: A 50 μH single-layer solenoid inductor has been designed to achieve the target C_{P} in Table 6. MV LISN inductor can experience high-frequency saturations due to high current. Thus, an air core is adopted. The inductance of a single-layer, air-core, solenoid inductor can be analyzed using the a relationship, where D, a, N, and μ₀ are the core diameter, the axial length, the # of turns, and the permeability of free space, respectively. The axial length, a can be represented by a=(N−1)p+d_{O}, where p is the winding pitch and d_{O} is the outer diameter of the conductor. Having an air core eliminates winding-to core parasitic capacitances. Thus, C_{P} becomes mostly caused by interwinding turn-to-turn capacitances. The total parasitic capacitance C_{P} can be analyzed using an empirical formula, where so is the air permittivity. Equation (12) provides some improved accuracy over the physical-based analytical models for C_{P} estimation.

$$\begin{matrix}L = \frac{{μλ}_{0} {N}^{2} D}{2} [ ln ( 1 + \frac{π D}{2 a} ) + \frac{1}{2.3 + 1.6 ( \frac{2 a}{D} ) + 0.44 {( \frac{2 a}{D} )}^{2}} ] & ( 11 ) \\ {C}_{P} = \frac{4 {ɛ}_{0} a}{π} [ 0.71 \frac{D}{a} + 1 + 2.4 {( \frac{D}{a} )}^{1.5} ] & ( 12 )\end{matrix}$$

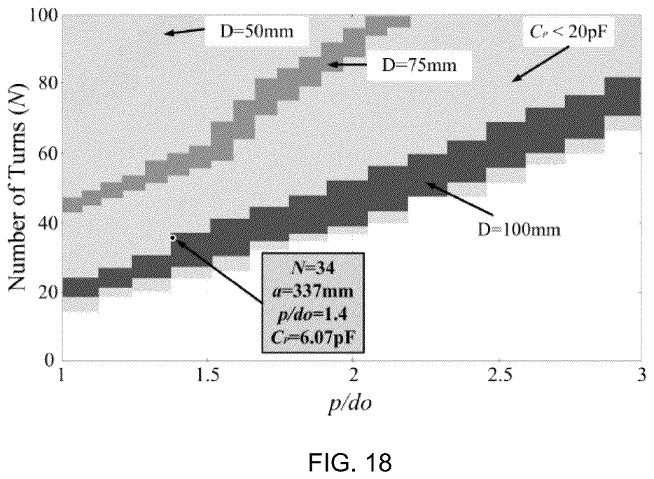

The goal of the inductor design process is to determine the optimum values for N, a, and p using equations (11) and (12) to meet the design constraints at L=50 μH and C_{P}<20 pF. Furthermore, it may be beneficial to obtain the smallest volume for the inductor to achieve a small form factor for the proposed LISN. Three values for D are considered in the parameter sweep simulations: 50 mm, 75 mm, and 100 mm. d_{O} is chosen as 6.9 mm considering AWG-3 wires necessary to obtain 75 A for the proposed LISN. FIG. 18 presents the results of the parameter sweep, where N is varied from 10 to 100 and p is varied from 1 to 3. The configurations for which 50 μH inductance is feasible are marked for three values of D. Additionally, all feasible configurations to achieve C_{P}<20 pF are marked. While having a smaller D can be helpful to make C_{P} smaller, it will result in a very large a due to the increased number of turns. As a tradeoff between low C_{P} and desired packaging and form factor for the inductor, point A is chosen from FIG. 18 as a possible design point, which corresponds to N=34, D=100 mm, a=337 mm, p/d_{O}=1.4, and C_{P}=6.07 pF. In addition to satisfying the C_{P} and L values constraints, this design point provides approximately 15% smaller volume for the inductor compared to the possible design points with D=50 mm and D=75 mm.

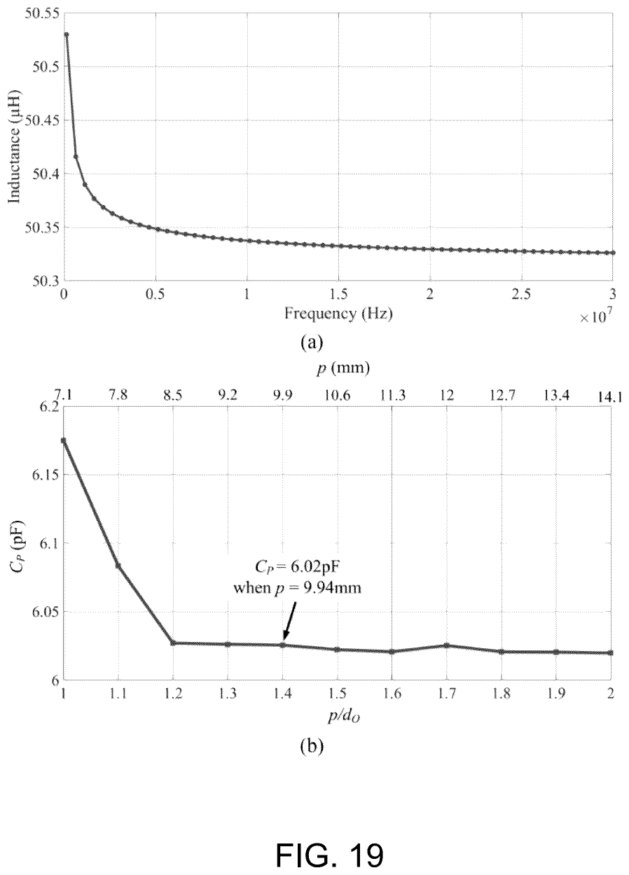

To further verify the chosen design point, the inductor is designed with the chosen design parameters from the parameter sweep to assess L and C_{P}. In FIG. 19, simulation results for the designed inductor is presented. In part (a) of FIG. 19 presents the frequency response for L and C_{P} variation is observed over p/do in part (b) of FIG. 19, when N=34, D=100 mm, and a=337 mm. It is apparent that L is close to 50 μH and for p/d_{O}=1.4 (p=9.94 mm) the simulated value for C_{P} with the chosen design parameters are 6.02 pF, which is close to the parameter sweep analysis result obtained with equations (11) and (12).

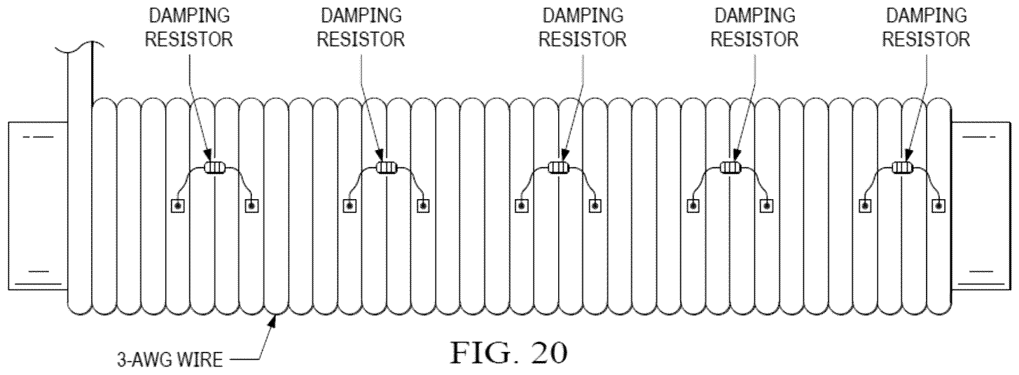

2) Experimental Validation of the Designed Inductor: Using the parameters discussed above, an air-core inductor has been implemented using 3-AWG (American wire gauge) lead wires with a voltage rating of 2.4 kV and 110 A capacity. It is shown in FIG. 20. A 3-D printed polyvinyl chloride (PVC) is used to prevent core saturation. A challenge regarding the inductor is the nonlinear impedance at the resonance point. Furthermore, CISPR 16-1-2 suggests that LISN inductors should be resistively damped to mitigate impedance resonances beyond SRF. Hence, resistive damping with a 680Ωshunt resistor in every four winding turns is applied to minimize this, at high frequencies, and comply with CISPR 16-1-2 standards.

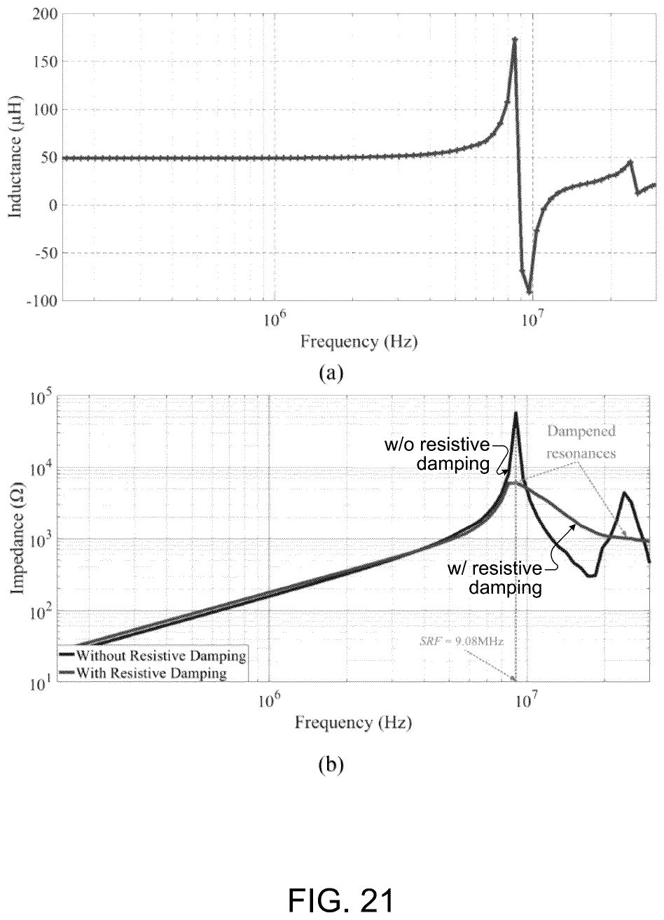

A network analyzer has been used to evaluate the designed inductor. Its measured frequency characteristics are shown in FIG. 21. The inductance remains steady at around 50 μH until its first self-resonance occurs, after which C_{P} begins to dominate the impedance as illustrated in part (a) of FIG. 21. As observed in part (b) of FIG. 21, the inductor has an SRF at 9.08 MHz, corresponding to a C_{P} of around 6.14pF, which satisfies the design goals in Table 6 and is close to the simulation results. Also, the shunt resistors dampened the self-resonances at and beyond SRF, increasing the bandwidth. The inductor specifications are briefly summarized and compared in Table 7.

TABLE 7
Designed inductor specifications

| Parameter | Simulated Values | | Measured Values | |
|---|---|---|---|---|
| Number of turns (N) | 34 | | 35 | |
| Core diameter (D) | 100 | mm | 105 | mm |
| Axial length (a) | 337 | mm | 342 | mm |
| Wire diameter (dₒ) | 6.9 | mm | 7 mm (AWG-3) | |
| Winding pitch (p) | 9.94 | mm | 10 | mm |
| Winding separation (p-dₒ) | 3.04 | mm | 3 mm (average) | |
| Inductance (L) | 50 | μH | 50 | μH |
| Parasitic capacitance (C_{P}) | 6.02 | pF | 6.14 | pF |
| Self-resonant frequency (SRF) | 9.18 | MHz | 9.08 | MHz |

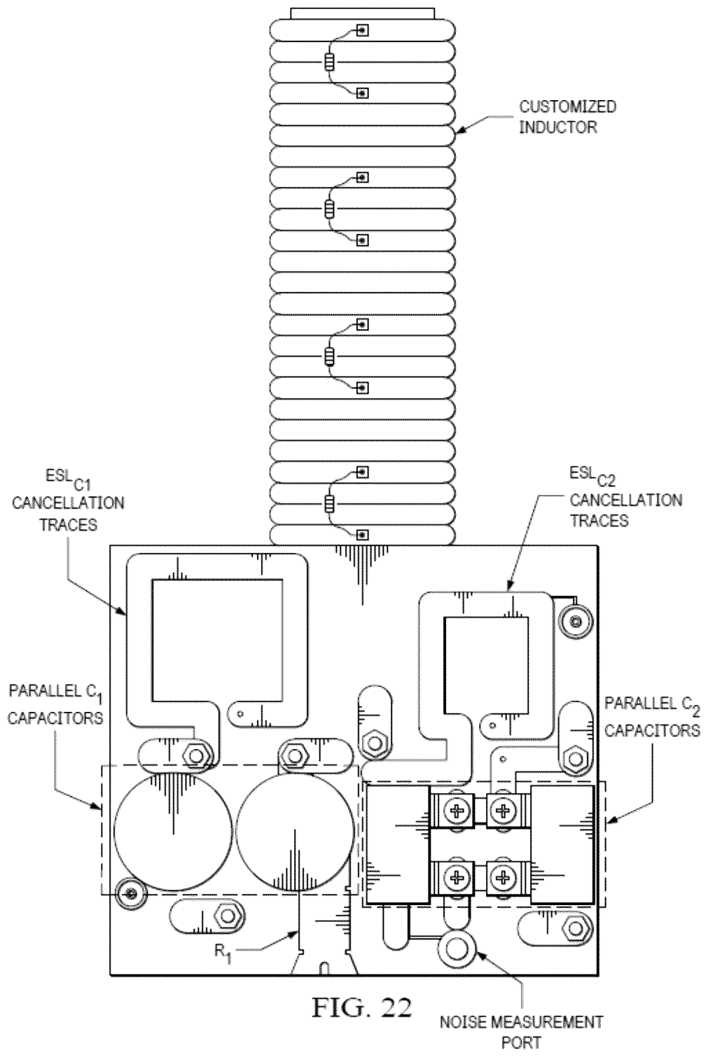

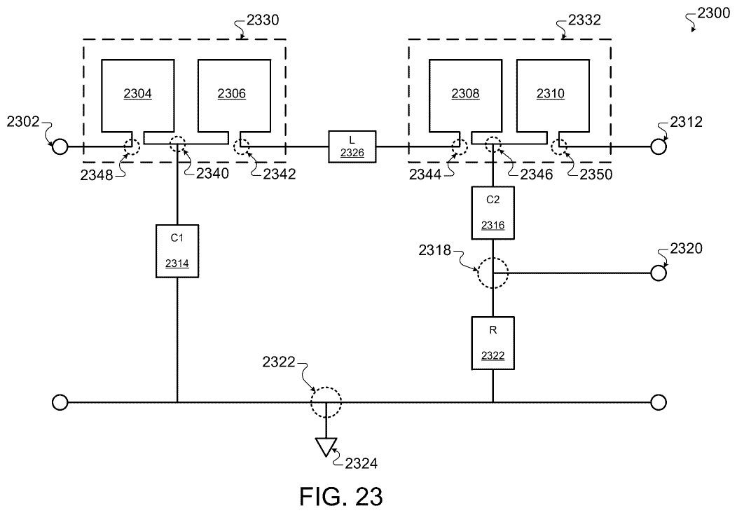

FIG. 23 illustrates an example circuit schematic of a LISN 2300 with modified wiring. The schematic 2300 is a representation of the circuit shown in FIG. 22. Similar to the LISN discussed above, the LISN 2300 is configured to handle medium voltage levels and included components that are rated for at least 1500 volts.

The LISN 2300 includes a power supply port 2302 that is configured to connect to a power source. The LISN 2300 includes a device under test (DUT) port 2312 that is configured to connect to the device under test. The LISN includes a measurement port 2320 that is configured to connect to a measurement device, such as a spectrum analyzer. The spectrum analyzer may collect data while the power supply port 2302 is connected to a power supply and the DUT port 2312 is connected to a DUT. The LISN 2300 may be connected to ground 2324 or another reference voltage.

The circuit schematic of the LISN 2300 includes representations of various components included in the LISN 2300. These components are rated for medium voltage applications, for example, 1500 volts. These components may have standard values depending on the applicable standard for the LISN 2300. The LISN 2300 includes an inductor 2326. The LISN 2300 includes two capacitors, a first capacitor 2314 and a second capacitor 2316. The LISN 2300 includes a resistor 2322.

The circuit schematic of the LISN 2300 includes representations of various circuit nodes between the various components. The first circuit node 2330 is connected to the power supply port 2302, the inductor 2326, and the first capacitor 2314. The second circuit node 2332 is connected to the inductor 2326, the DUT port 2312, and the second capacitor 2316. The third circuit node 2318 is connected to the second capacitor 2316, the measurement port 2320, and the resistor 2322. The fourth circuit node 2322 is connected to the first capacitor 2314, the resistor 2322, and ground 2324.

Because the components of the LISN 2300 are rated for medium voltage, they each have significant parasitic elements that can alter the functionality of the LISN 2300. To counteract this, the first circuit node 2330 and the second circuit node 2332 are configured to generate mutual inductances that counteract some of the parasitics. In the example LISN 2300, the first circuit node 2330 includes two wire loops, a wire loop 2304 and a wire loop 2306 that are described in detail above. The first circuit node 2330 also includes various circuit sub-nodes that represent the ends of the wire loop 2304 and a wire loop 2306. The wire loop 2304 is connected to circuit sub-node 2348 and circuit sub-node 2340. The circuit sub-node 2348 is connected to the power supply port 2302. The circuit sub-node 2340 is connected to the first capacitor 2314. The wire loop 2306 is connected to circuit sub-node 2342 and circuit sub-node 2340. The circuit sub-node 2342 is connected to the inductor 2326. The wire loop 2304 and the wire loop 2306 may be overlapping traces on a printed circuit board. The wire loop 2304 and the wire loop 2306 generate inductances and mutual inductances counteract some of the parasitics of other components.

In the example LISN 2300, the second circuit node 2332 includes two wire loops, a wire loop 2308 and a wire loop 2310 that are described in detail above. The second circuit node 2332 also includes various circuit sub-nodes that represent the ends of the wire loop 2308 and a wire loop 2310. The wire loop 2308 is connected to circuit sub-node 2344 and circuit sub-node 2346. The circuit sub-node 2344 is connected to the inductor 2326. The circuit sub-node 2346 is connected to the second capacitor 2316. The wire loop 2310 is connected to circuit sub-node 2346 and circuit sub-node 2350. The circuit sub-node 2350 is connected to the device under test port 2312. The wire loop 2308 and the wire loop 2310 may be overlapping traces on a printed circuit board. The wire loop 2308 and the wire loop 2310 generate inductances and mutual inductances counteract some of the parasitics of other components.

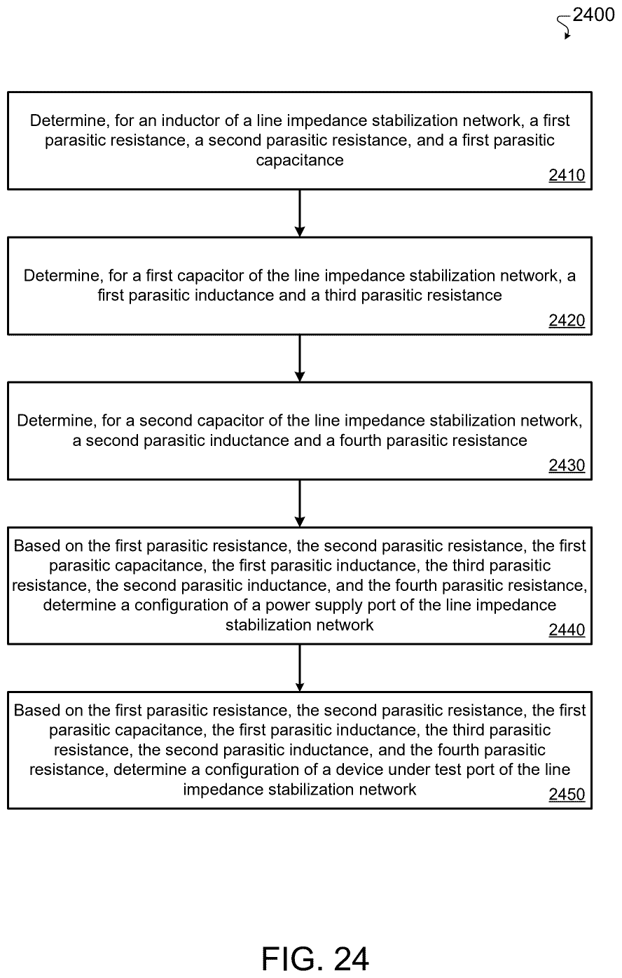

FIG. 24 is a flowchart of an example process 2400 for determining wiring modifications for a LISN capable of handling medium voltage. In general, the process 2400 determines the various parasitic elements of the various components in a LISN, such as the LISN described above. Based on those parasitic elements, the process 2400 may determine the configuration of the wires connected to the power supply port and the device under test port. In some implementations, the process 2400 may be performed by a single computing device, which may be a virtual device and/or split across multiple computing devices that may include virtual devices. In some implementations, the process 2400 may be performed by an application that is running on the computing device, multiple computing devices, and/or a virtual computing device. In this example, the process 2400 will be described as being performed by an application.

The application determines, for an inductor of a line impedance stabilization network, a first parasitic resistance, a second parasitic resistance, and a first parasitic capacitance (2410). The first parasitic resistance may be a parasitic resistance that is in parallel with the inductor. The second parasitic resistance may be a parasitic resistance that is series with the inductor. The first parasitic capacitance may be in parallel with the inductor.

The application determines, for a first capacitor of the line impedance stabilization network, a first parasitic inductance and a third parasitic resistance (2420). The first parasitic inductance and the third parasitic resistance may both be in series with the first capacitor. The application determines, for a second capacitor of the line impedance stabilization network, a second parasitic inductance and a fourth parasitic resistance (2430). The second parasitic inductance and the fourth parasitic resistance may both be in series with the second capacitor. The inductor, first capacitor, and the second capacitor may have voltage ratings of at least 1500 volts. These voltage ratings may impact the values of the parasitic components.

Based on the first parasitic resistance, the second parasitic resistance, the first parasitic capacitance, the first parasitic inductance, the third parasitic resistance, the second parasitic inductance, and the fourth parasitic resistance, the application determines a configuration of a power supply port of the line impedance stabilization network (2440). The configuration of a power supply port may include overlapping wire loops. The size of the overlapping wire loops of the power supply port may be based on voltage rating of the LISN, the current rating of the LISN, the power rating of the LISN, the first parasitic resistance, the second parasitic resistance, the first parasitic capacitance, the first parasitic inductance, the third parasitic resistance, the second parasitic inductance, the fourth parasitic resistance, and/or the value of the resistor connected to ground and the measurement port. The overlapping wire loops of the power supply port may be loops on a printed circuit board. The size of the overlapping wire loops of the power supply port may include a width of the trace; a radius, enclosed area, and/or circumference of a round trace; and/or the length of a side, enclosed area, and/or perimeter of a square trace. In some implementations, the size and/or shape of the overlapping wire loops of the power supply port may be different. The configuration of the overlapping wire loops of the power supply port may include an amount of overlapping and a location of a connection point between the overlapping wire loops of the power supply port.

Based on the first parasitic resistance, the second parasitic resistance, the first parasitic capacitance, the first parasitic inductance, the third parasitic resistance, the second parasitic inductance, and the fourth parasitic resistance, the application determines a configuration of a device under test port of the line impedance stabilization network (2450). The configuration of a DUT port may include overlapping wire loops. The size of the overlapping wire loops of the DUT port may be based on voltage rating of the LISN, the current rating of the LISN, the power rating of the LISN, the first parasitic resistance, the second parasitic resistance, the first parasitic capacitance, the first parasitic inductance, the third parasitic resistance, the second parasitic inductance, the fourth parasitic resistance, and/or the value of the resistor connected to ground and the measurement port. The overlapping wire loops of the DUT port may be loops on a printed circuit board. The size of the overlapping wire loops may include a width of the trace; a radius, enclosed area, and/or circumference of a round trace; and/or the length of a side, enclosed area, and/or perimeter of a square trace. In some implementations, the size and/or shape of the overlapping wire loops of the DUT port may be different. The configuration of the overlapping wire loops of the DUT port may include an amount of overlapping and a location of a connection point between the overlapping wire loops of the DUT port. In some implementations, the overlapping wire loops of the DUT ports may be different than the overlapping wire loops of the power supply port in size and/or shape.

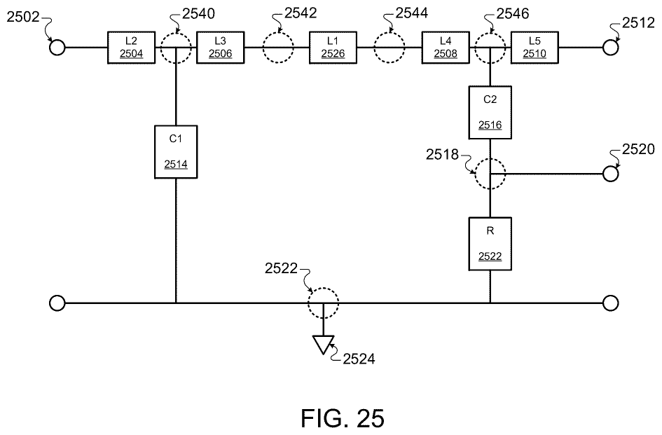

FIG. 25 illustrates an example circuit schematic of a LISN 2500 were modified wires are represented by equivalent inductors. The LISN 2500 may be similar to the LISN 2300 but with the wire loops 2304, 2306, 2308, and 2310 of FIG. 23 replaced by an equivalent inductor. The LISN 2500 is configured to handle medium voltage levels and included components that are rated for at least 1500 volts.

The LISN 2500 includes a power supply port 2502 that is configured to connect to a power source. The LISN 2500 includes a device under test (DUT) port 2512 that is configured to connect to the device under test. The LISN 2500 includes a measurement port 2520 that is configured to connect to a measurement device, such as a spectrum analyzer. The spectrum analyzer may collect data while the power supply port 2502 is connected to a power supply and the DUT port 2512 is connected to a DUT. The LISN 2500 may be connected to ground 2524 or another reference voltage.

The circuit schematic of the LISN 2500 includes representations of various components included in the LISN 2500. These components are rated for medium voltage applications, for example, 1500 volts. These components may have standard values depending on the applicable standard for the LISN 2500. The LISN 2500 includes a first inductor 2526. The LISN 2500 includes two capacitors, a first capacitor 2514 and a second capacitor 2516. The LISN 2300 includes a resistor 2522.

The wire loops of LISN 2300 of FIG. 23 have been replaced by their equivalent inductors. The second inductor 2504, the third inductor 2506, the fourth inductor 2508, and the fifth inductor 2510 remain implement using wire loops that may be on a printed circuit board. Each of the second inductor 2504, the third inductor 2506, the fourth inductor 2508, and the fifth inductor 2510 have a value that is configured to counteract the parasitic components of the other components of the LISN 2500, such as the medium voltage components. The second inductor 2504 and the third inductor 2506 generate a first mutual inductance and the fourth inductor 2508 and the fifth inductor 2510 generate a second mutual inductance that also helps counteract the parasitic components of the other components of the LISN 2500, such as the medium voltage components.

The circuit schematic of the LISN 2300 includes representations of various circuit nodes between the various components. The first circuit node 2542 is connected to the first inductor 2526 and the third inductor 2506. The second circuit node 2544 is connected to the first inductor 2526 and the fourth inductor 2508. The third circuit node 2540 is connected to the second inductor 2504, the third inductor 2506, and the first capacitor 2514. The fourth circuit node 2522 is connected to the first capacitor 2514 and the resistor 2522. The fifth circuit node 2546 is connected to the fourth inductor 2508, the fifth inductor 2510, and the second capacitor 2516. The sixth circuit node 2518 is connected to the second capacitor 2516 and the resistor 2522. The seventh circuit node is the power supply port 2502 that is connected to the second inductor 2504. The eighth circuit node is the DUT port 2512 that is connected to the fifth inductor 2510. The measurement port 2520 is connected to the sixth circuit node 2518. The fourth circuit node 2522 is connected to ground 2524 or another reference voltage.

The second inductor 2504 and the third inductor 2506 may be wire loops on a printed circuit and may overlap. Similarly, the fourth inductor 2508 and the fifth inductor 2510 may be wire loops on a printed circuit and may overlap. The width, shape, enclosed area, perimeter, amount of overlap, and/or other characteristics may be based on the values of the parasitic components of the first capacitor 2514, the second capacitor 2516, the resistor 2522, and/or the first inductor 2526 and/or based on the voltage rating, the current rating, or the power rating of the line impedance stabilization network.

This specification describes presents a single-stage 1.5 kV, 75 A rated LISN design that meets CISPR-16 band-B requirements. The proposed LISN eliminates the necessity of additional passive components and subsequent complexity, while providing stable high frequency operations. Comprehensive simulation studies and rigorous experimental tests have been done to identify the impacts of parasitic parameters (i.e., the parasitic capacitance, C_{P} in MV inductors, and large ESL in MV capacitors). Parametric sweep analyses have been performed to determine parasitic parameter values of capacitors and inductors. Based on new understandings, some methods to substantially reduce parasitic challenges have been discussed. Specifically, design procedures for an inductor and a mitigation method for ESL have been presented. LISN operational parameters have been studied, focusing on high-frequency performance. The proposed LISN provides a stable source impedance without any oscillations at high frequencies. It is shown that the proposed ESL cancellation can achieve around 10 dB improvement in high frequency noise couplings over other approaches. Also, it offers >45 dB isolations from a source, resulting in EMI measurements with high fidelity. Such sufficient isolation from a power source and high-frequency coupling ensures accurate measurement. Furthermore, proposed parasitic reduction techniques do not rely on extra passive elements in the LISN circuit, while providing better specifications and characteristics than example counterparts.

While several implementations have been provided in the present disclosure, it should be understood that the disclosed systems and methods may be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted or not implemented.

Also, techniques, systems, subsystems, and methods described and illustrated in the various implementations as discrete or separate may be combined or integrated with other systems, modules, techniques, or methods without departing from the scope of the present disclosure. Other items shown or discussed as directly coupled or communicating with each other may be indirectly coupled or communicating through some interface, device, or intermediate component, whether electrically, mechanically, or otherwise. Other examples of changes, substitutions, and alterations are ascertainable by one skilled in the art and could be made without departing from the spirit and scope disclosed herein.

What is claimed is:

1. A line impedance stabilization network comprising:
an inductor that defines a first circuit node and a second circuit node and that has a first parasitic resistance, a second parasitic resistance, and a first parasitic capacitance;
a first capacitor that is connected to the first circuit node, that defines a third circuit node, and that has a first parasitic inductance, and a third parasitic resistance;
a second capacitor that is connected to the second circuit node, that defines a fourth circuit node, and that has a second parasitic inductance and a fourth parasitic resistance; and
a resistor that is connected to the fourth circuit node and the third circuit node,
wherein a configuration of the first circuit node generates a first mutual inductance that is based on the first parasitic resistance, the second parasitic resistance, the first parasitic capacitance, the first parasitic inductance, the third parasitic resistance, the second parasitic inductance, and the fourth parasitic resistance, and
wherein a configuration of the second circuit node generates a second mutual inductance that is based on the first parasitic resistance, the second parasitic resistance, the first parasitic capacitance, the first parasitic inductance, the third parasitic resistance, the second parasitic inductance, and the fourth parasitic resistance.

2. The line impedance stabilization network of claim 1, wherein the first circuit node and the third circuit node are configured to connect to a power supply.

3. The line impedance stabilization network of claim 1, wherein the second circuit node and the third circuit node are configured to connect to a device under test.

4. The line impedance stabilization network of claim 1, wherein the fourth circuit node is configured to connect to a measurement device.

5. The line impedance stabilization network of claim 1, wherein the inductor, the first capacitor, and the second capacitor have a rating of at least 1500 volts.

6. The line impedance stabilization network of claim 1, wherein the configurations of the first circuit node and the second circuit node each comprise overlapping traces on a printed circuit board.

7. The line impedance stabilization network of claim 1, wherein the first circuit node comprises:
a first wire loop that defines a first circuit sub-node and a second circuit sub-node; and
a second wire loop that is connected to the second circuit sub-node and that defines a third circuit sub-node,
wherein the second circuit sub-node is connected to the first capacitor, and
wherein the third circuit sub-node is connected to the inductor.

8. The line impedance stabilization network of claim 7, wherein the first wire loop overlaps the second wire loop.

9. The line impedance stabilization network of claim 1, wherein the second circuit node comprises:
a first wire loop that defines a first circuit sub-node and a second circuit sub-node; and
a second wire loop that is connected to the second circuit sub-node and that defines a third circuit sub-node,
wherein the first circuit sub-node is connected to the inductor, and
wherein the second circuit sub-node is connected to the second capacitor.

10. The line impedance stabilization network of claim 9, wherein the first wire loop overlaps the second wire loop.

11. A computer-implemented method, comprising:
determining, for an inductor of a line impedance stabilization network, a first parasitic resistance, a second parasitic resistance, and a first parasitic capacitance;
determining, for a first capacitor of the line impedance stabilization network, a first parasitic inductance and a third parasitic resistance;
determining, for a second capacitor of the line impedance stabilization network, a second parasitic inductance and a fourth parasitic resistance;
based on the first parasitic resistance, the second parasitic resistance, the first parasitic capacitance, the first parasitic inductance, the third parasitic resistance, the second parasitic inductance, and the fourth parasitic resistance, determining a configuration of a power supply port of the line impedance stabilization network; and
based on the first parasitic resistance, the second parasitic resistance, the first parasitic capacitance, the first parasitic inductance, the third parasitic resistance, the second parasitic inductance, and the fourth parasitic resistance, determining a configuration of a device under test port of the line impedance stabilization network.

12. The method of claim 11, wherein the configuration of the power supply port comprises a first wire loop and second wire loop that overlaps the first wire loop.

13. The method of claim 11, wherein the configuration of the device under test port comprises a first wire loop and second wire loop that overlaps the first wire loop.

14. The method of claim 11, comprising:
determining a voltage rating, a current rating, or a power rating of the line impedance stabilization network,
wherein the configuration of the power supply port is further based on the voltage rating, the current rating, or the power rating of the line impedance stabilization network, and
wherein the configuration of the device under test port is further based on the voltage rating, the current rating, or the power rating of the line impedance stabilization network.

15. The method of claim 11, wherein the inductor, the first capacitor, and the second capacitor have a rating of at least 1500 volts.

16. A line impedance stabilization network, comprising:
a first inductor that defines a first circuit node and a second circuit node;
a first capacitor that defines a third circuit node and a fourth circuit node
a second capacitor that defines a fifth circuit node and a sixth circuit node;
a resistor that is connected to the sixth circuit node and fourth circuit node;
a second inductor that defines a seventh circuit node and is connected to the third circuit node;
a third inductor that is connected to the first circuit node and the third circuit node;
a fourth inductor that is connected to the second circuit node and the fifth circuit node; and
a fifth inductor that is connected to the fifth circuit node and that defines an eighth circuit node.

17. The line impedance stabilization network of claim 16, wherein the second inductor overlaps the third inductor.

18. The line impedance stabilization network of claim 16, wherein the fourth inductor overlaps the fifth inductor.

19. The line impedance stabilization network of claim 16, wherein the second inductor, the third inductor, the fourth inductor, and the fifth inductor are implemented using traces on a printed circuit board.

20. The line impedance stabilization network of claim 19, wherein a width of the traces is based on a voltage rating, a current rating, or a power rating of the line impedance stabilization network.
